(19) United States
(12) Patent Application Publication
(10) Pub. No.: US 2025/0374462 A1
(43) Pub. Date: Dec. 4, 2025

(54) FLOW-RESTRICTING STRUCTURE AND DISPLAY DEVICE HAVING THE SAME

(71) Applicant: Samsung Display Co., LTD., Yongin-si (KR)

(72) Inventors: YOUNG MOO KWON, Yongin-si (KR); HEESUNG LIM, Yongin-si (KR)

(21) Appl. No.: 19/049,123

(22) Filed: Feb. 10, 2025

(30) Foreign Application Priority Data
May 28, 2024 (KR) 10-2024-0069265

(51) Int. Cl. H05K 5/03

(52) U.S. Cl. CPC H05K 5/03

(57) ABSTRACT

A display device includes a display panel, a cover glass facing the display panel and having an outer edge, the cover glass defining a groove therein which extends along the outer edge, a light blocking layer which is in the groove, and an adhesive layer which includes an optically clear resin and is between the display panel and the cover glass at the groove in the cover glass, the adhesive layer combining the display panel and the cover glass to each other.

This application claims priority to Korean Patent Application No. 10-2024-0069265 filed on May 28, 2024, and all the benefits accruing therefrom under 35 U.S.C. § 119, the entire contents of which are incorporated herein by reference.

### BACKGROUND

### (a) Field

The present disclosure relates to a display device.

### (b) Description of the Related Art

In general, an electronic device such as a smart phone, a digital camera, a laptop computer, a navigation system, and a smart television which provides images to users includes a display device for displaying the images. The display device generates an image and provides the generated image to a user through a display screen.

A window of a display device may be attached to a display panel. The window and the display panel may be attached to each other by an adhesive layer.

### SUMMARY

The embodiments provide a display device which improves the problem of resin flowing during the formation of an adhesive layer.

A display device according to an embodiment includes: a display panel; an adhesive layer disposed on the display panel; and a cover glass disposed on the adhesive layer, where the adhesive layer includes an optically clear resin, the cover glass includes a groove disposed along a circumference of the display panel, and a light blocking member of a light blocking layer is provided in the groove.

The adhesive layer may be partially disposed inside the groove.

The display device may further include a light blocking member disposed at an edge of the cover glass.

The groove is disposed in plural numbers along a circumference of the display panel.

A cross-sectional shape of the groove may be a triangle.

A cross-sectional shape of the groove may be a quadrangle.

A cross-sectional shape of the groove may be a circle.

The display device may further include a polarization layer disposed between the adhesive layer and the display panel.

The display device may further include a reflection reduction layer disposed between the polarization layer and the adhesive layer.

The adhesive layer may not be disposed on a side surface of the display panel.

A display device according to an embodiment includes: a display panel; an adhesive layer disposed on the display panel; a cover glass disposed on the adhesive layer; and a light blocking member disposed at an edge of the cover glass, where the adhesive layer includes an optically clear resin, and the light blocking member includes a groove disposed along a circumference of the display panel.

The adhesive layer may be partially disposed inside the groove.

The groove may be disposed in plural numbers along a circumference of the display panel.

A cross-sectional shape of the groove may be a triangle.

A cross-sectional shape of the groove may be a quadrangle.

A cross-sectional shape of the groove may be a circle.

The display device may further include a polarization layer disposed between the adhesive layer and the display panel.

The display device may further include a reflection reduction layer disposed between the polarization layer and the adhesive layer.

The adhesive layer may not be disposed on a side surface of the display panel.

The groove disposed in the light blocking member may not penetrate the light blocking member.

According to the embodiments, a display device which improves the problem of resin flowing during the formation of an adhesive layer and improves reliability can be provided.

### BRIEF DESCRIPTION OF THE DRAWINGS

The above and other advantages and features of this disclosure will become more apparent by describing in further detail embodiments thereof with reference to the accompanying drawings, in which:

FIG. 1 schematically illustrates a cross-section of a display device according to an embodiment.

FIGS. 2A and 2B schematically show a method for providing a display device according to an embodiment.

FIG. 3 schematically illustrates planar shapes of a first adhesive layer and a second adhesive layer according to an embodiment.

FIG. 4 schematically illustrates a cross-section of the first adhesive layer and the second adhesive layer shown in FIG. 3.

FIG. 5 schematically illustrates planar shapes of a display panel and a cover glass of the display device according to an embodiment.

FIG. 6 is a cross-sectional view of FIG. 5 taken along the line VI-VI′.

FIG. 7 and FIG. 8 illustrate an embodiment of a display panel and a cover glass of a display device in which the groove is not included.

FIGS. 9 to 12 are cross-sectional views taken along the line VI-VI′ in a display device according to embodiments.

FIGS. 13 to 17 are cross-sectional views taken along the line VI-VI′ in a display device according to embodiments

### DETAILED DESCRIPTION

Hereinafter, with reference to the accompanying drawing, embodiments of the present disclosure will be described in detail such that a person of an ordinary skill can easily practice it in the technical field to which the present disclosure belongs. The present invention may be implemented in several different forms and is not limited to the embodiments described herein.

In order to clearly describe the present disclosure, parts without explanation or relationship are omitted, and the same reference sign is used for identical or similar components throughout the specification.

In addition, the size and thickness of each component shown in the drawing are arbitrarily shown for better understanding and ease of description, and thus the present disclosure is not necessarily limited to what is shown. In the drawings, the thickness of layers, films, panels, regions, etc., are exaggerated for clarity. Further in drawing, the thickness of some layers and regions is exaggerated for better understanding and ease of description.

It will be understood that when an element such as a layer, film, region, or substrate is referred to as being related to another element such as being “on” another element, it can be directly on the other element or intervening elements may also be present. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Further, throughout the specification, the word “on” a target element will be understood to mean positioned above or below the target element, and will not necessarily be understood to mean positioned “at an upper side” based on an opposite to gravity direction.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

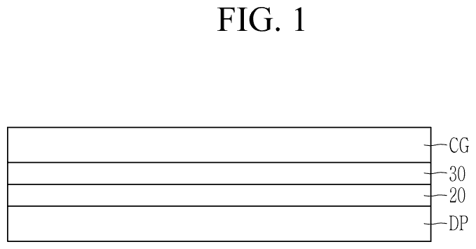

Hereinafter, a display device according to the present embodiment will be described in detail with reference to the accompanying drawings. FIG. 1 schematically illustrates a cross-section of a display device according to the present embodiment. Referring to FIG. 1, a display device according to the present embodiment may include a display panel DP and a cover glass CG which is disposed on the display panel DP. A polarization layer 20 may be disposed between the display panel DP and the cover glass CG, and an adhesive layer 30 may be disposed on the polarization layer 20. The display panel DP and cover glass CG may be bonded to each other through the adhesive layer 30. A collective display panel may include the display panel DP together with the polarization layer 20. Here, the cover glass CG may contact the collective display panel (e.g., at the polarization layer). As being in contact, elements or layers may form an interface therebetween.

In an embodiment, the display device and various components or layers of the stacked structures thereof may be disposed in a plane defined by a first direction and a second direction crossing each other. A thickness direction of the display device and various components or layers thereof may be defined along a third direction intersecting the plane.

The adhesive layer 30 may include an optically clear resin (OCR). In this case, the adhesive layer 30 may be formed or provided by applying a material of the OCR with an inkjet equipment and then curing the material to form the adhesive layer 30 as the OCT which is cured.

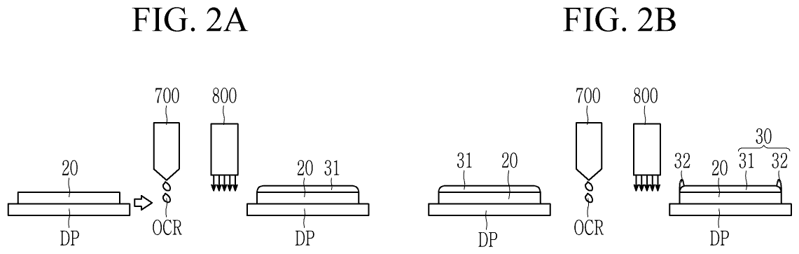

FIGS. 2A and 2B schematically show a method for providing a display device, including the applying and curing of the OCR. Referring to FIG. 2A, a material of the OCR which is uncured is first applied on to a stacked structure including the display panel DP and the polarization layer 20. In this case, the uncured material of the OCR may be applied using a nozzle 700. In an embodiment, the stacked structure shown in FIG. 2A may be disposed relative to the nozzle 700 (indicated by the arrow between the stacked structure and the nozzle 700 in FIG. 2A.).

Although not show, the stacked structure having the material of the OCR thereon from the nozzle 700 may be further disposed relative to a light source (e.g., under an ultraviolet (UV) light source 800). Here, the stacked structure may be under the nozzle 700 and the UV light source 800, with respect to the vertical direction shown in FIG. 2A.

A first adhesive layer 31 having cured OCR material may be formed on the polarization layer 20, such as through a curing process using the UV light source 800 and the stacked structure having uncured OCR material being disposed in the path of the UV light. A first process of providing the display device may include the images in FIG. 2A from a first stacked structure (20 and DP as a preliminary stacked structure) to a second stacked structure (20, 31 and DP as an intermediate stacked structure), inclusive of the nozzle 700 and UV light source 800 therebetween.

Then, referring to FIG. 2B, in a second process of providing the display device, a material of the OCR is applied again, this time onto the second stacked structure provided in the first process. In detail, the OCR material is applied on an edge portion of the display panel DP having the first cured layer (e.g., the first adhesive layer 31) thereon, using the nozzle 700 and cured using the UV light source 800, similar to that which is described above for the images in FIG. 2A. Through this second process, a second adhesive layer 32 as a second cured layer may be formed at the edge, to provide a third stacked structure (20, DP, 31 and 32). While FIG. 2B shows the second adhesive layer 32 protruded at left and right sides of the third stacked structure (e.g., opposing sides which are spaced apart in a first direction), it will be understood that the second cured layer may be provided along other sides of the third stacked structure which oppose each other in a second direction. In an embodiment, a pattern of the second adhesive layer 32 may be disposed along an entirety of the edge of the underlying stacked structure, without being limited thereto.

As shown in FIGS. 2A and 2B, the first adhesive layer 31 and the second adhesive layer 32 may together form the adhesive layer 30. In FIGS. 2A and 2B, the boundaries of the first adhesive layer 31 and the second adhesive layer 32 are shown as distinct, but this is for better understanding and ease of description, and in an embodiment, the first adhesive layer 31 and the second adhesive layer 32 may include the same material. Therefore, the boundary between the first adhesive layer 31 and the second adhesive layer 32 may not be visible.

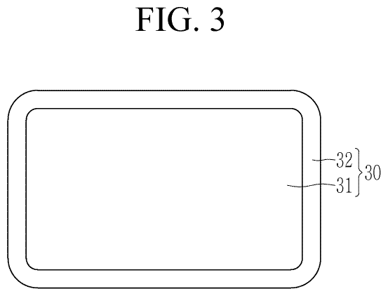

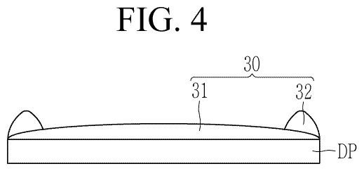

FIG. 3 schematically illustrates planar shapes of the first adhesive layer 31 and the second adhesive layer 32. Although not explicitly shown, FIG. 4 schematically illustrates a cross-section of the first adhesive layer 31 and the second adhesive layer 32 relative to a display panel DP. The display panel DP indicated in FIG. 4 may be representative of the display panel DP together with the polarization layer 20 in FIG. 1 where the polarization layer 20 is omitted for convenience of illustration. That is, taking FIGS. 1-4 together, the adhesive layer 30 may contact the polarization layer 20, such as to form an interface therebetween, or may contact the display panel DP (like at the polarization layer 20 thereof or at another layer).

In FIG. 4, the boundary of the first adhesive layer 31 and the second adhesive layer 32 are shown as distinct, but this is for better understanding and ease of description, and in an embodiment, the first adhesive layer 31 and the second adhesive layer 32 may include the same material. Therefore, the boundary between the first adhesive layer 31 and the second adhesive layer 32 may not be distinguished.

In addition, in FIGS. 2A and 2B to FIG. 4, it is illustrated that the adhesive layer 30 includes the first adhesive layer 31 and the second adhesive layer 32, but in an embodiment, the adhesive layer 30 may be one layer formed through a single process (e.g., a monolayer).

In this way, the adhesive layer 30 is formed to attach the cover glass CG to a stacked structure including the display panel DP, with the polarization layer 20 (like in FIG. 1) or without the polarization layer 20 (like in FIG. 4), for example) during a process of providing (e.g., manufacturing) of the display device, and the adhesive layer 30 is formed through a process of applying and curing an optically clear resin (OCR). However, the optically clear resin (OCR) has flowability, and therefore control of flowability during application may be difficult. Therefore, during the OCR application process to form the adhesive layer 30, resin may overflow past the edges of the layer within a stacked structure to which the OCR material is applied. When the applied resin overflows the edges, it may be absorbed into other layers of the stacked structure which form the display device, or problems such as separation of the interfaces of layers which are in contact with each other may occur, which may affect the reliability of the display device.

However, the display device according to an embodiment solves problems such as overflowing or vapor generation of the applied OCR by forming a groove in the cover glass CG and/or a light blocking member BM to guide or restrict movement of the material for forming the OCR along the layer to which the material is applied. Hereinafter, detailed embodiments will be described with reference to drawings.

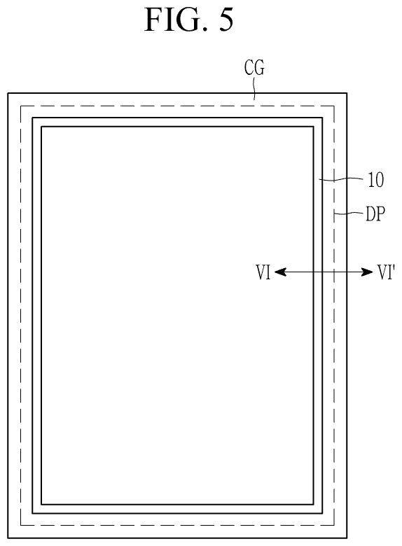

FIG. 5 schematically illustrates planar shapes of the display panel DP and the cover glass CG of the display device according to an embodiment. Referring to FIG. 5, the cover glass CG includes a groove 10 which is disposed along the edge of the display panel DP while surrounding the display panel DP, such as be be extended along a circumference or periphery of the display panel DP. The groove 10 may be a recess which is defined extended into a thickness of the cover glass CG and open along the thickness direction to face the display panel DP and various components or layers thereof. Portions of the cover glass CG may define the recess. In an embodiment, the groove 10 is recessed into a partial thickness of the cover glass CG.

In an embodiment, the groove 10 may be disposed along the edge of the display panel DP to be inside an outer edge of the display panel DP, such that the outer edge surrounds the groove 10. In an embodiment, where the dotted line in FIG. 5 indicates a boundary of a display area of the display panel DP at which an image is displayed, the groove 10 may be disposed along the boundary to surround the display area of the display panel DP. Here, the boundary may be where the display area and an inner end of the light blocking member BM (e.g., corresponding to a non-display area of the display panel DP) meet each other. That is, inner end of the light blocking member BM may define a boundary between a display area and a non-display area within the display device, without being limited thereto.

The groove 10 may have a closed loop shape in the plan view, to surround a planar area of the display panel DP or the polarization layer 20 (like a display area thereof). The groove 10 may be continuous along respective sides or outer edges of the display device.

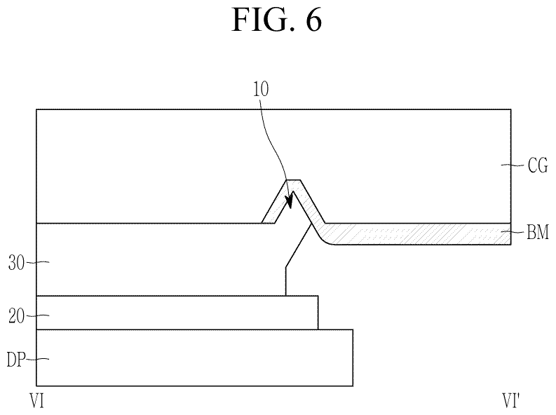

FIG. 6 is a cross-sectional view of FIG. 5 taken along the line VI-VI′. Referring to FIG. 6, the polarization layer 20 and the adhesive layer 30 are disposed on the display panel DP, and the cover glass CG may be disposed on the adhesive layer 30. As shown in FIG. 6, the light blocking member BM as a light blocking layer may be positioned at an edge of the cover glass CG. Referring to FIGS. 5 and 6, the light blocking member BM may be extended along the edge of the cover glass CG and corresponding to an extension of the groove 10.

The groove 10 is disposed at the edge of the cover glass CG, and a part of the adhesive layer 30 may extend into the groove 10 to be disposed inside the groove 10. In an embodiment, the material of the adhesive layer 30 may completely fill the groove 10 without being limited thereto. Referring to FIG. 6, for example, the display panel DP includes a side surface extending along the outer edge of the cover glass CG (e.g., an end side surface of the polarization layer 20 and/or the display panel DP shown in FIG. 6. In a direction along the display device (e.g., horizontal in FIG. 6 or along the plane shown in FIG. 5), an end of the adhesive layer 30 which is closest to the outer edge of the cover glass CG is adjacent to the side surface of the display panel DP. That is, the end of the adhesive layer 30 is not disposed on the side surface. As being ‘adjacent’, the end of the adhesive layer 30 may be non-overlapping, such as being spaced apart from the side surface.

The light blocking member BM may be disposed inside the groove 10. The light blocking member BM may have a cross-sectional profile corresponding to that of the groove 10. The light blocking member BM may form an open groove which faces the display panel DP and various components or layers thereof. The open groove may include a recessed portion of the light blocking member BM which corresponds to a thickness of the cover glass CG, but is not limited thereto. That is, an opening of the recessed portion of the light blocking member BM may be coplanar with an opening of the groove 10 in the cover glass CG. Therefore, even if the adhesive layer 30 is filled inside the groove 10, it may not be visible from the outside, owing to the light-blocking property of the light blocking member BM.

As shown in FIG. 5 and FIG. 6, the groove 10 may be disposed extended into a thickness of the cover glass CG and lengthwise along the edge of the display panel DP, and the adhesive layer 30 may be disposed inside the groove 10. In other words, when resin flows from an inner area of the display panel DP and toward an outer edge thereof during the process of forming the adhesive layer 30 with OCR, the resin may not flow outside of the outer edge of the display panel DP but may pool inside the groove 10. That is, the groove 10 functions like a dam and may prevent resin from overflowing the display panel DP and/or the polarization layer 20. As shown in FIG. 6, the light blocking member BM is formed inside the groove 10, and thus the groove 10 may not be visible from the outside.

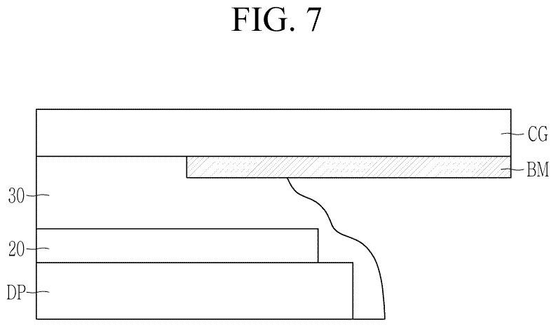

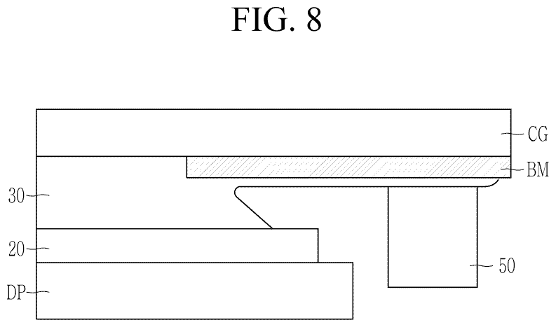

FIG. 7 and FIG. 8 illustrate an embodiment in which the groove 10 is not included.

As shown in FIG. 7, when the groove 10 does not exist in a layer facing a stacked structure of the display device, the resin may overflow and be absorbed into other structures or layers such as the display panel DP and/or the polarization layer 20. This may deteriorate the reliability of the display device. That is, as shown in FIG. 7, when the adhesive layer 30 is formed on a region other than a region or empty space between the polarization layer 20 and the cover glass CG, for example, top and side surfaces of the display panel DP or the side surface of the polarization layer 20, the reliability of the display device may be reduced.

In addition, as shown in FIG. 8, when the resin flows without being restricted by the groove 10, it may affect the reliability of the adhesive tape 50 which may be attached later. That is, as shown in FIG. 8, when the resin flows past a target area of the stacked structure, the adhesive layer 30 may be formed on the light blocking member BM at a location between the light blocking member BM and another layer or component. In this case, adherence to the adhesive tape 50 as the another layer which is disposed on the light blocking member BM may be reduced.

However, the display device according to the present embodiment solves this problem by including the groove 10 disposed at or adjacent to the outer edge of the cover glass CG and allowing the resin to be positioned within the groove 10.

Previously, FIG. 5 and FIG. 6 shows a configuration in which the grooves 10 are formed in a single row in a direction from the display panel DP to an outer edge of the cover glass CG, but the number of grooves may vary.

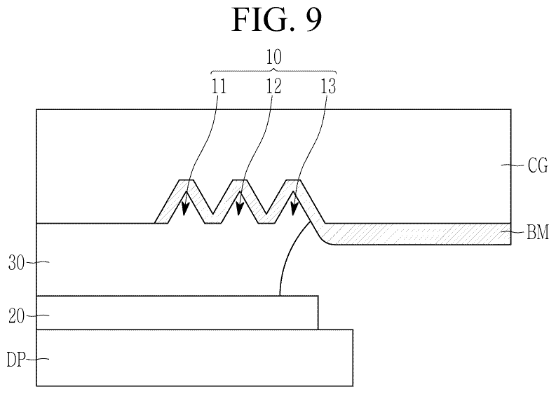

FIG. 9 illustrates the same cross-section as shown in FIG. 6 in a display device according to an embodiment. Referring to FIG. 9, a display device according to the present embodiment is the same as the display device of FIG. 6, except that a groove 10 includes a first groove 11 as a first sub-groove, a second groove 12 as a second sub-groove, and a third groove 13 as a third sub-groove which are arranged along the cover glass CG in the direction from the display panel DP to the outer edge of the cover glass CG. Detailed descriptions of the same components are omitted. When the plurality of grooves 10 are included in this way, even if there is a relatively large amount of resin overflowing in the direction toward the outer edge of the cover glass CG, it can be controlled stably.

The display device according to the previously-described includes the display panel DP, the polarization layer 20, the adhesive layer 30, and the cover glass CG (or the display panel DP, the adhesive layer 30, and the cover glass CG, based on the configuration in FIG. 4, for example), but the display device according to the other embodiment may further include a reflection reduction layer 400 (e.g., anti-reflection layer) disposed between the polarization layer 20 and the adhesive layer 30.

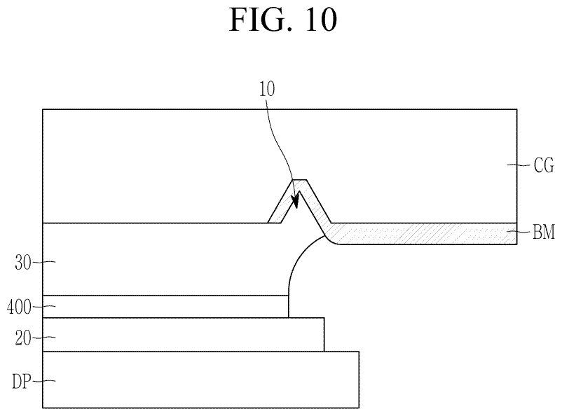

FIG. 10 shows the same cross-section as shown in FIG. 6, for an embodiment. Referring to FIG. 10, a display device according to the present embodiment is the same as the display device of FIG. 6, except that a reflection reduction layer 400 is further included between a polarization layer 20 and an adhesive layer 30. Detailed descriptions of the same components are omitted. Referring to FIG. 10, the reflection reduction layer 400 may reduce reflection from external light. This may be applied to a vehicle display and the like.

In addition, in the previously described embodiment, the cross-sectional shape of the groove 10 is shown as a triangle, but the cross-sectional shape of the groove is not limited thereto.

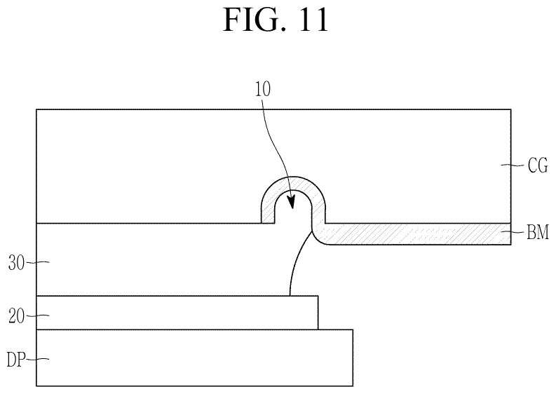

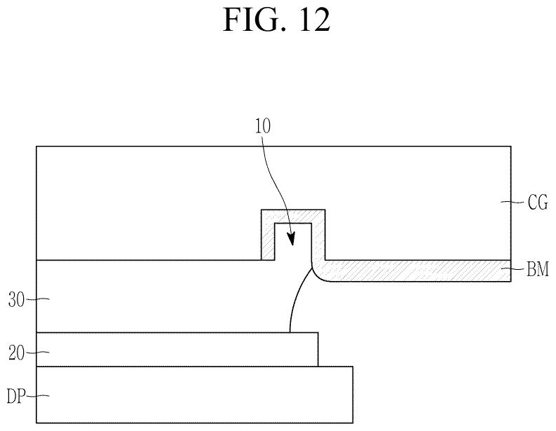

FIG. 11 and FIG. 12 show the same cross-section as shown in FIG. 6 for an embodiment. As shown in FIG. 11, a cross-section shape of a groove 10 may be circular or semi-circular, and as shown in FIG. 12, a cross-section shape of the groove 10 may be a quadrangle. The groove 10 with these various shapes may be formed by processing a cover glass CG to define a groove 10 therein having a cross-sectional shape. Referring to FIG. 5, for example, such cross-sectional shape may be extended along a length of a respective side of the cover glass CG to define the groove 10 lengthwise extended along a respective outer edge of the cover glass CG.

In the above, a configuration for controlling the flow of resin by forming the groove 10 in the cover glass CG was described, but in an embodiment, the groove may be formed in the light blocking member BM.

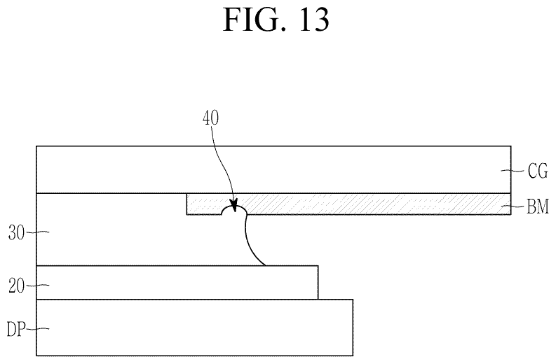

FIG. 13 shows the same cross-section as shown in FIG. 6 for an embodiment. Referring to FIG. 13, in a display device according to the present embodiment, the cover glass CG may have a flat lower surface which is closest to the display panel DP. Here, a light blocking member BM disposed at an edge of a cover glass CG may include or define a groove 40. As shown in FIG. 13, an adhesive layer 30 may be disposed inside the groove 40. The material of the adhesive layer 30 may completely fill the groove 40 without being limited thereto, where an opening of the groove 40 is coplanar with a lower surface of the light blocking member BM. That is, the flow of resin may be controlled by the groove 40 disposed in the light blocking member BM. The groove 40 disposed in the light blocking member BM may serve as a dam to prevent the flow of resin toward an outer edge of the outer edge of the display device. Other components are the same as those in FIG. 6, and therefore no further description will be provided. In FIG. 13, the shape of the cross-section of the groove 40 is shown as a circle (e.g., being curved like that of a semi-circle), but is not limited thereto. The cross-sectional shape and number of grooves 40 may vary.

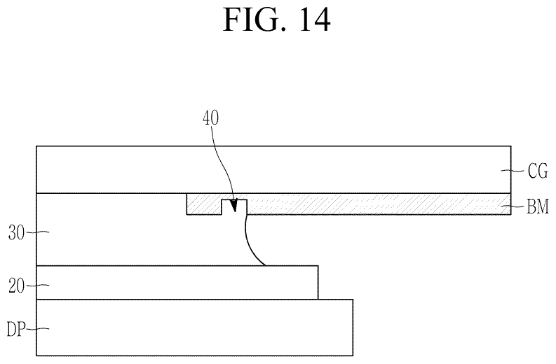

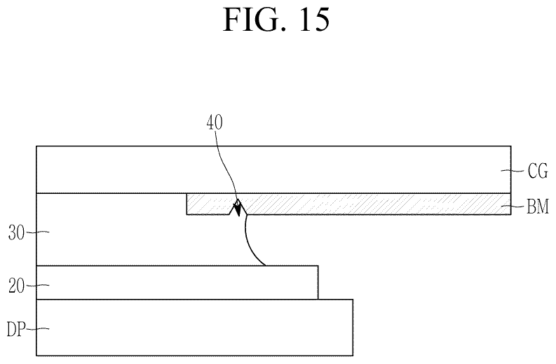

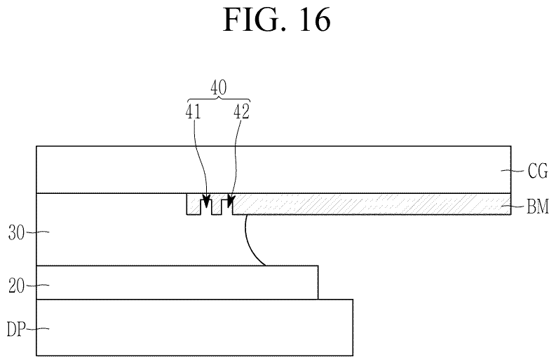

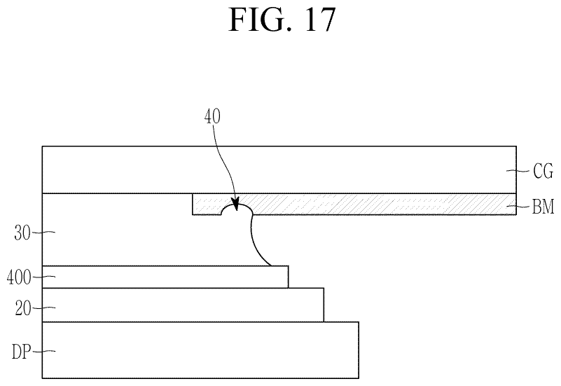

In an embodiment, the groove 40 is partially recessed into a thickness of the light blocking layer (e.g., the light blocking member BM), so as to not penetrate a thickness of the light blocking member BM. That is, even in an embodiment in which the groove 40 is formed in the light blocking member BM, the number and shape of the grooves 40 may vary. FIG. 14 to FIG. 17 show the same cross-section as shown in FIG. 13, for various embodiments. In various embodiments, a shape of a groove 40 may be a quadrangle as shown in FIG. 14, or may be a triangle as shown in FIG. 15. In addition, as shown in FIG. 16, a groove 40 may be provided in plurality including a first groove 41 as a first sub-groove and a second groove 42 as a second sub-groove which is closer to the outer edge of the cover glass CG than the first sub-groove. In addition, as shown in FIG. 17, a reflection reduction layer 40 disposed between a polarization layer 20 and an adhesive layer 30 may be further included.

In the embodiment of FIG. 5 to FIG. 10, the groove 10 is disposed within the cover glass CG, and a separate light blocking member BM is disposed inside the groove 10 to prevent the groove 10 from being visible. However, in the embodiments of FIG. 13 to FIG. 17, the groove 40 may be visible from the outside since the groove 40 is formed in the light blocking member BM.

As described above, the display device according to the present embodiment includes a recessed groove disposed extended along (or parallel to) the edge of the cover glass CG or disposed extended along (or parallel to) the edge of the light blocking member BM. The recessed groove may prevent a flowable material such as a resin from overflowing or being disposed close to an outer edge of the display device during the formation of the adhesive layer 30 containing OCR and may improve the reliability of the display device.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A display device comprising:
a display panel;
a cover glass facing the display panel and having an outer edge, the cover glass defining a groove therein which extends along the outer edge;
a light blocking layer which is in the groove; and
an adhesive layer which comprises an optically clear resin and is between the display panel and the cover glass at the groove in the cover glass, the adhesive layer combining the display panel and the cover glass to each other.

2. The display device of claim 1, wherein:
the adhesive layer extends into the groove.

3. The display device of claim 1, wherein:
the light blocking layer extends from inside the groove to the outer edge of the cover glass.

4. The display device of claim 1, wherein:
the groove is provided in plural including sub-grooves each extending along the outer edge of the cover glass.

5. The display device of claim 1, wherein:
a cross-sectional shape of the groove is a triangle.

6. The display device of claim 1, wherein:
a cross-sectional shape of the groove is a quadrangle.

7. The display device of claim 1, wherein:
a cross-sectional shape of the groove is a semi-circle.

8. The display device of claim 1, further comprising a polarization layer between the adhesive layer and the display panel.

9. The display device of claim 8, further comprising a reflection reduction layer between the polarization layer and the adhesive layer.

10. The display device of claim 1, wherein:
the display panel includes a side surface extending along the outer edge of the cover glass, and
in a direction along the display device, an end of the adhesive layer which is closest to the outer edge of the cover glass is adjacent to the side surface of the display panel.

11. A display device comprising:
a display panel;
a cover glass facing the display panel and having an outer edge;
a light blocking layer at the outer edge of the cover glass, the light blocking layer defining a groove therein which extends along the outer edge; and
an adhesive layer which comprises an optically clear resin and is between the display panel and the light blocking layer at the groove in the light blocking layer, the adhesive layer combining the display panel and the cover glass to each other.

12. The display device of claim 11, wherein:
the adhesive layer extends into the groove.

13. The display device of claim 11, wherein:
the groove is provided in plural numbers in the light blocking layer, the grooves including sub-grooves each extending along the outer edge of the cover glass.

14. The display device of claim 11, wherein:
a cross-sectional shape of the groove is a triangle.

15. The display device of claim 11, wherein:
a cross-sectional shape of the groove is a quadrangle.

16. The display device of claim 11, wherein:
a cross-sectional shape of the groove is a semi-circle.

17. The display device of claim 11, further comprising a polarization layer between the adhesive layer and the display panel.

18. The display device of claim 17, further comprising a reflection reduction layer between the polarization layer and the adhesive layer.

19. The display device of claim 11, wherein:
the display panel includes a side surface extending along the outer edge of the cover glass, and
in a direction along the display device, an end of the adhesive layer which is closest to the outer edge of the cover glass is adjacent to the side surface of the display panel.

20. The display device of claim 11, wherein:
the groove is recessed into a partial thickness of the light blocking layer.
